(19) United States
(12) Patent Application Publication
(10) Pub. No.: US 2016/0118243 A1
(43) Pub. Date: Apr. 28, 2016

(54) METHODS FOR PREPARING A TITANIUM OXIDE FILM AND A COMPOSITE FILM COMPRISING THE SAME

(71) Applicant: National Taiwan University, Taipei City (TW)

(72) Inventors: Feng-Yu TSAI, Taipei City (TW); Yuan-Yu LIN, Taipei City (TW)

(21) Appl. No.: 14/692,099

(22) Filed: Apr. 21, 2015

(30) Foreign Application Priority Data
Oct. 23, 2014 (TW) 103136662

(51) Int. Cl. H01L 21/02; H01L 23/00

(52) U.S. Cl. CPC H01L 21/02186; H01L 21/02282; H01L 23/564

(57) ABSTRACT

The present invention relates to a method for preparing a titanium oxide film and a method for preparing a composite film comprising a titanium oxide film. Particularly, the present invention relates to a method for preparing the titanium oxide film which serves as a passivation layer for the oxide semiconductor. In the present method for preparing the passivation layer, a low-reactive metal alkoxide compound is used as a precursor to form the passivation layer by the atomic layer deposition. Therefore, the deterioration of the oxide semiconductor during the preparation process may be avoided.

### CROSS REFERENCE TO RELATED APPLICATION

This application claims the benefits of the Taiwan Patent Application Serial Number 103136662, filed on Oct. 23, 2014, the subject matter of which is incorporated herein by reference.

### BACKGROUND OF THE INVENTION

1. Field of the Invention

The present invention relates to methods for preparing a titanium oxide film and a composite film comprising the same, and especially to a method for preparing an oxide film as a passivation layer for an oxide semiconductor manufacturing process.

2. Description of Related Art

Semiconductor materials are widely used in the thin-film transistor preparation to serve as the signal converter switches of the display device. Typical semiconductor materials can be classified into amorphous silicon, polysilicon, oxides, and organic materials. Among these semiconductor materials, since the oxide semiconductors have advantages of high mobility, high optical transmittance, capability of large-area production, and application on low temperature process etc., they comply with the development trend of future displays employing minimized or flexible substrates.

However, in the present methods for preparing a thin-film transistor including the oxide semiconductor, the plasma-enhanced chemical vapor deposition (PECVD) is generally employed for the deposition of a passivation layer. However, during its deposition process, the impact of high-energy plasma easily deteriorates the oxide semiconductor by reducing the oxide into metal. Therefore, after the deposition of the passivation layer, annealing is further required. For example, under the plasma impact, the oxygen content in the oxide semiconductor may reduce, thereby degrading the electrical properties and the stability of the oxide semiconductor. Therefore, after the passivation layer deposition is completed, high-temperature calcination is further required to oxidize the oxide semiconductor layer again, so as to ensure its semiconductor characteristics. Thus, the entire preparation process of the thin-film transistor is complex, and requires the high-temperature calcination. Especially, flexible plastic substrates cannot endure such high temperature, so these plastic substrates cannot be used in the aforementioned preparation process of the thin-film transistor.

In order to avoid the deterioration caused by the plasma-enhanced chemical vapor deposition, the passivation layer is commonly formed by a thermally activated chemical vapor deposition. In the thermally activated vapor deposition, a high-reactive metal organic precursor is used for deposition of the passivation layer. However, the high-reactive precursor is easy to react with the oxide semiconductor, resulting in defects occurred in the oxide semiconductor, and increasing the carrier concentration of the oxide semiconductor, thus degrading the electrical properties thereof.

To avoid the deterioration of the oxide semiconductor during the preparation process of the thin-film transistor, what is needed in the art is to provide a novel method for preparing an oxide semiconductor thin-film transistor, to ensure the quality of the oxide semiconductor during the preparation process, and maintain high mobility, high optical transmittance and so on.

### SUMMARY OF THE INVENTION

An object of the present invention is to provide a method for preparing a titanium oxide film, and particularly to a method for preparing the titanium oxide film which serves as a passivation layer for the oxide semiconductor thin-film transistor. In the present method, a low-reactive metal alkoxide compound is used as a precursor to form the passivation layer, such that the deposition need no assistance of plasma and may avoid the deterioration of the oxide semiconductor caused by high-reactive precursor.

The method for preparing a titanium oxide film provided by the present invention, comprises: (A) providing a metal alkoxide compound and water in contact with a semiconductor substrate: and (B) using the metal alkoxide compound as a precursor to form a titanium oxide film on a surface of the semiconductor substrate by an atomic layer deposition; wherein the titanium oxide film may have a gas penetration of 0.1 g/m²-day or less.

In the step (A) according to one aspect of the present invention, the metal alkoxide compound as the precursor is at least one of the compounds represented by Formula (I):

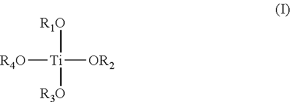

wherein, each R₁, R₂, R₃, and R₄ are independently selected from a branched or linear C₁₋₁₀ alkyl group, wherein R₁, R₂, R₃, and R₄ may be the same as or different from each other, but is not particularly limited. However, the metal alkoxide compound may be at least one selected from the group consisting of: Ti(OCH₃)₄, Ti(OC₂H₅)₄, Ti[OCH(CH₃)₂]₄, Ti(OC₄H₉)₄, and Ti[OCH₂CH(C₂H₅)(CH₂)₃CH₃]₄. Preferably, the metal alkoxide compound is Ti[OCH(CH₃)₂]₄.

In the step (A) according to one aspect of the present invention, the semiconductor substrate may be an oxide semiconductor substrate, and the oxide semiconductor substrate may be formed of any oxide semiconductor material known in the art. For example, the oxide semiconductor substrate is made of at least one selected from the group consisting of: zinc oxide, tin oxide, iron oxide, chromium oxide, indium oxide, copper oxide, nickel oxide, and cadmium oxide, and preferably zinc oxide.

Furthermore, in the step (A) according to one aspect of the present invention, the metal alkoxide compound as the precursor is heated to 60-150° C. Thus, in the step (B) according to one aspect of the present invention, the atomic layer deposition is preferably a thermally activated atomic deposition.

In addition, in the method for preparing the titanium oxide film provided by the present invention, the thickness of the formed titanium oxide film is not particularly limited, as long as it is able to provide an efficient passivation to protect the oxide semiconductor layer. For example, its thickness may be about 5 to 100 nm, and the cycle numbers of the atomic layer deposition may be about 500 to 10,000 times, but is not particularly limited.

In addition, another object of the present invention is to provide a method for preparing a composite film comprising a titanium oxide, and particularly to a method for preparing the composite film which serves as a passivation layer for the oxide semiconductor thin-film transistor. The composite film includes: a titanium oxide layer on the oxide semiconductor layer, formed by an atomic layer deposition using a low-reactive metal alkoxide compound as a precursor; and another metal oxide films formed on the titanium oxide layer. Therefore, the method for preparing a composite film comprising a titanium oxide provided by the present invention can effectively avoid the deterioration of the oxide semiconductor layer during the formation of the passivation layer.

The method for preparing a composite film comprising a titanium oxide film provided by the present invention may comprise: (A) providing a metal alkoxide compound and water in contact with a semiconductor substrate: and (B) using the metal alkoxide compound as a precursor to form a titanium oxide film on a surface of the semiconductor substrate by an atomic layer deposition; and (C) depositing at least one metal oxide film on the titanium oxide film to form a composite film, wherein the composite film has a gas penetration of 0.1 g/m²-day or less.

In the step (A) according to one aspect of the present invention, the metal alkoxide compound as the precursor is at least one of the compounds represented by Formula (I):

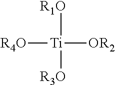

wherein, each R₁, R₂, R₃, and R₄ are independently selected from a branched or linear C₁₋₁₀ alkyl group.

In Formula (I), R₁, R₂, R₃, and R₄ may be the same as or different from each other, but is not particularly limited. However, the metal alkoxide compound may be preferably at least one selected from the group consisting of: Ti(OCH₃)₄, Ti(OC₂H₅)₄, Ti[OCH(CH₃)₂]₄, Ti(OC₄H₉)₄, and Ti[OCH₂CH(C₂H₅)(CH₂)₃CH₃]₄, and more preferably Ti[OCH(CH₃)₂]₄.

In the step (A) according to one aspect of the present invention, the semiconductor substrate may be an oxide semiconductor substrate, and the oxide semiconductor substrate may be made of any oxide semiconductor material known in the art. For example the oxide semiconductor substrate is made of at least one selected from the group consisting of: zinc oxide, tin oxide, iron oxide, chromium oxide, indium oxide, copper oxide, nickel oxide, and cadmium oxide, and preferably zinc oxide.

In addition, in the step (A) according to one aspect of the present invention, the metal alkoxide compound as the precursor is heated to 60-150° C. Thus, in the step (B) according to one aspect of the present invention, the atomic layer deposition is preferably a thermally activated atomic deposition.

In the step (C) according to one aspect of the present invention, the metal compound film deposited on the surface of the titanium oxide film may be made of any materials suitable for serving as the passivation layer material of the thin-film transistor. For example, the metal compound film may be made of at least one selected from the group consisting of: titanium oxide, aluminum oxide, hafnium oxide, zirconium oxide, and a mixture thereof. In addition, in the step (C), the metal oxide film may be prepared by a conventional deposition method known in the art, for example, atomic layer deposition, chemical vapor deposition, and physical vapor deposition.

For example, in the method for preparing a composite film comprising a titanium oxide film provided by the present invention, after depositing a first titanium oxide film of about 3 nm on the semiconductor substrate, a first aluminum oxide film of about 2 nm may be deposited on the first titanium oxide film by a conventional deposition method known in the art, and then a second titanium oxide film of about 3 nm may be deposited on the first aluminum oxide film, followed by the deposition of a second aluminum oxide film of about 2 nm on the second titanium oxide film. The above steps may be repeated 7 times to obtain a composite film of about 35 nm, to serve as the passivation layer. However, the present invention is not limited thereto, as long as in the method for preparing the composite film, a metal alkoxide compound is first used as the precursor to deposit the titanium oxide film on the surface of the oxide semiconductor to form a titanium oxide film, followed by depositing the materials of the at least one metal oxide film subsequently on the titanium oxide film. In addition, the deposited thickness thereof is not particularly limited, and can be varied according to the design of the oxide semiconductor thin-film transistor. For example, the composite film may comprise a titanium oxide layer of about 3 nm, and a hafnium oxide layer of about 32 nm; or alternatively, the composite film may comprise repeatedly and sequentially stacked layers of titanium oxide, hafnium oxide, and aluminum oxide.

Since a protective film can be formed after the titanium oxide film (for example, 3 nm) is deposited on the surface of the oxide semiconductors, the oxide semiconductor layer can be prevented from the deterioration caused by the high-reactive precursor such as aluminum oxide and so on.

Furthermore, in the present invention, the thickness of the prepared composite film is not particularly limited, as long as it is able to provide an efficient passivation to protect the oxide semiconductor layer.

### BRIEF DESCRIPTION OF THE DRAWINGS

FIGS. 1 and 2 show the schematic diagrams of the preparation method according to Example 1 of the present invention.

FIG. 3 shows the schematic diagram of the passivation layer structure according to Example 2 of the present invention.

FIG. 4 shows the test result according to Test Example 1 of the present invention.

### DETAILED DESCRIPTION OF THE PREFERRED EMBODIMENT

### Example 1

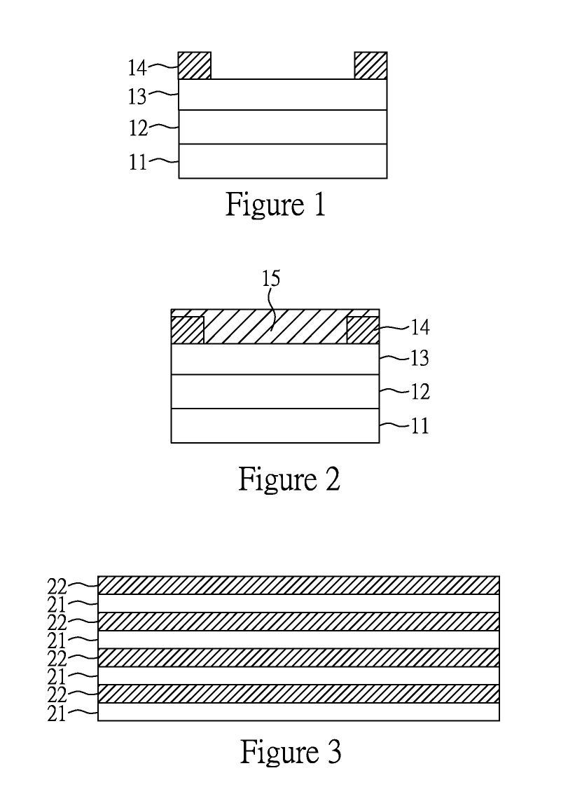

This Example provides a method for preparing a titanium oxide film serving as a passivation layer of an oxide thin-film transistor. First, referring to FIG. 1, a zinc oxide thin-film transistor substrate was provided, including sequentially stacked a patterned conductive glass 11, a dielectric layer 12, a zinc oxide semiconductor layer 13, and an electrode layer 14 formed on the zinc oxide semiconductor layer 13. Then, referring to FIG. 2, titanium tetraisopropoxide (Ti[OCH(CH₃)₂]) and water were provided as the precursor, and heated to 80° C. Next, a titanium oxide layer 15 of 35 nm was deposited on the zinc oxide semiconductor layer 13 and the electrode 14 by the atomic layer deposition at a deposition temperature of 150° C., to complete the zinc oxide thin-film transistor of this Example. The detailed preparation parameters are summarized in Table 1.

### Example 2

This Example provides a method for preparing a composite film including a titanium oxide film, to serve as a passivation layer of an oxide thin-film transistor. First, the zinc oxide film transistor substrate as shown in FIG. 1 was provided, and then a composite film comprising titanium oxide was formed thereon, as shown in FIG. 3. The method for preparing the composite film included the following steps: titanium tetraisopropoxide (Ti[OCH(CH₃)₂]) and water were provided as the precursor, and heated to 80° C. Then, a titanium oxide layer 21 of 3 nm was deposited on the zinc oxide semiconductor layer 13 by the atomic layer deposition at a deposition temperature of 150° C. Then, trimethyl aluminum and water were provided as the precursor, and an aluminum oxide layer 22 of 2 nm was formed on the titanium oxide layer 21 by the atomic layer deposition. The depositions of the titanium oxide layer 21 and the aluminum oxide layer 22 were repeated 7 times, to form the composite film as a passivation layer. Then, the oxide thin-film transistor of this example was completed. The detailed preparation parameters are summarized in Table 1.

TABLE 1

| | | Pulse | Exposure | Purge | | |
|---|---|---|---|---|---|---|
| | | time | time | time | Number of | |
| | Precursor | (s) | (s) | (s) | cycles | |
| Example 1 | Titanium | 0.1 | 0 | 20 | 2333 | |
| | tetraisopropoxide | | | | | |
| | water | 0.02 | 0 | 20 | | |
| Example 2 | Titanium | 0.1 | 0 | 20 | 200 | 7 |
| | tetraisopropoxide | | | | | |
| | water | 0.02 | 0 | 20 | | |
| | Trimethylaluminum | 0.03 | 0 | 8 | 20 | |
| | water | 0.02 | 0 | 8 | | |

### Comparative Example 1

The oxide film provided by Comparative Example 1 is shown in FIG. 1, wherein no passivation layer was formed on the zinc oxide semiconductor layer.

### Comparative Example 2

In Comparative Example 2, trimethyl aluminum and water were used as the precursors, and an aluminum oxide layer of 35 nm as a passivation layer was deposited on the zinc oxide semiconductor layer 13 by the atomic layer deposition at a deposition temperature of 150° C.

### Comparative Example 3

In Comparative Example 3, tetrakis(dimethylamido)hafnium and water were used as the precursors, and an hafnium oxide layer of 35 nm in thickness as a passivation layer was deposited on the zinc oxide semiconductor layer 13 shown in FIG. 1 by the atomic layer deposition at a deposition temperature of 150° C.

### Comparative Example 4

In Comparative Example 4, tetrakis(dimethylamido)zirconium and water were used as the precursors, and an zirconium oxide layer of 35 nm in thickness as a passivation layer was deposited on the zinc oxide semiconductor layer 13 shown in FIG. 1 by the atomic layer deposition at a deposition temperature of 150° C.

### Comparative Example 5

In Comparative Example 5, tetrakis(dimethylamido)titanium and water were used as the precursors, and an titanium oxide layer of 35 nm in thickness as a passivation layer was deposited on the zinc oxide semiconductor layer 13 shown in FIG. 1 by the atomic layer deposition at a deposition temperature of 150° C.

TABLE 2

| | | Pulse | Exposure | Purge | |
|---|---|---|---|---|---|
| | | time | time | time | Number |
| | Precursor | (s) | (s) | (s) | of cycles |
| Comparative | Trimethylaluminum | 0.03 | 0 | 8 | 350 |
| Example 2 | water | 0.02 | 0 | 8 | |
| Comparative | Tetrakis(dimethyl- | 0.1 | 0 | 20 | 350 |
| Example 3 | amido)hafnium | | | | |
| | water | 0.02 | 0 | 20 | |
| Comparative | tetrakis(dimethyl- | 0.1 | 0 | 20 | 350 |
| Example 4 | amido)zirconium | | | | |
| | water | 0.02 | 0 | 20 | |
| Comparative | Tetrakis(dimethyl- | 0.1 | 0 | 20 | 875 |
| Example 5 | amido)titanium | | | | |
| | water | 0.02 | 0 | 20 | |

### Comparative Example 6

In Comparative Example 6, the plasma enhanced chemical vapor deposition technique was employed to form a silicon oxide (SiOₓ) layer of 35 nm in thickness on the zinc oxide semiconductor layer 13 shown in FIG. 1, to serve as a passivation layer.

### Comparative Example 7

In Comparative Example 7, the evaporation method was employed to form an aluminum layer of 35 nm in thickness on the zinc oxide semiconductor layer 13 shown in FIG. 1, to serve as a passivation layer.

### Comparative Example 8

In Comparative Example 8, the sputtering method was employed to form an aluminum oxynitride (AlOₓN_{y}) layer of 35 nm in thickness on the zinc oxide semiconductor layer 13 shown in FIG. 1, to serve as a passivation layer.

### Test Example 1

### Transmission Characteristics Test of Oxide Thin-Film Transistor

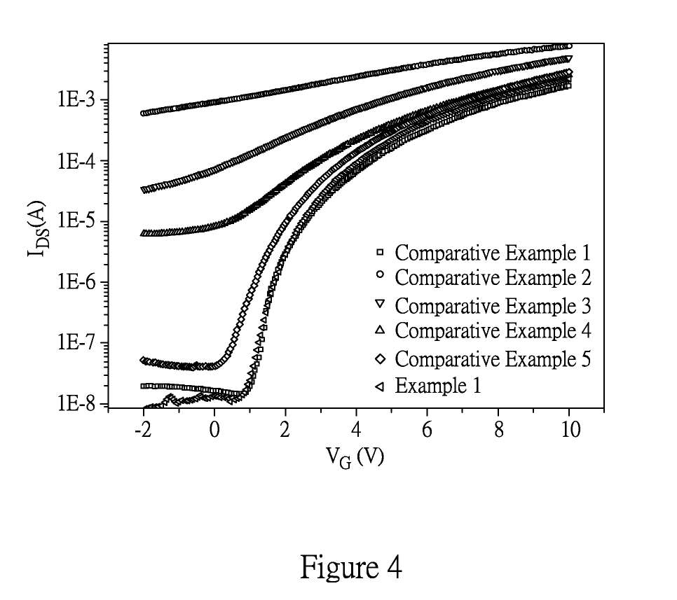

In Test Example 1, the electrical transmission characteristics of the oxide thin-film transistors prepared in Example 1 and Comparative Examples 1 to 5 were measured, and the test results are shown in FIG. 4. The test conditions for the thin-film transistors are listed as follows: voltage applied to gate (V_{G}): from −2V to 10V, voltage applied to drain (V_{DS}): 8V. The packaged zinc oxide thin-film transistors of Comparative Examples 1 to 5 had an increased off current and a reduced threshold voltage, indicating that the packaging layers of Comparative Examples 1 to 5 caused the defects in the oxide semiconductor.

It can be confirmed from the results in FIG. 4 that the titanium oxide passivation layer formed by the method of the present invention (Example 1) had an electrical property curve similar to the oxide film transistor on which a passivation layer was not formed (Comparative Example 1). Therefore, the preparation method provided by the present invention did not cause damage to the electrical property of the oxide semiconductor. On the other hand, since Comparative Examples 2 to 4 used high-reactive precursors to form the passivation layers on the oxide semiconductor layers by the atomic layer deposition, the measured curves of the electrical properties thereof were shifted from the curve of Comparative Example 1, indicating that during the deposition of the passivation layer, the oxide semiconductor layer was detrimentally affected, resulting in deterioration of the electrical properties.

### Test Example 3

### Gas Penetration

In Test Example 3, the moisture penetrations of the passivation layers prepared in Examples 1 to 2 and Comparative Examples 6 to 8 were measured. The test method included the following steps: a passivation layer film was deposited on a PET film, and then placed in a closed pipeline. An end of the pipeline was connected to a water vapor having a fixed pressure, while another end of the pipeline was connected to a moisture detection instrument. First, the pipeline was vacuumed to remove the residue gas in the pipeline. Then, water vapor having a fixed pressure of 1 kg/cm² was introduced into the pipeline, which penetrated the passivation layers and reached the moisture detection instrument at the other end of the pipeline. The penetrated water volume was detected by the moisture detection instrument to obtain the moisture penetration of this passivation layer. The test results are summarized in Table 3.

TABLE 3

| | Deposition | Material of | Moisture penetration |
|---|---|---|---|
| | method | passivation layer | (g/m²-day) |
| Example 1 | ALD | titanium oxide | 3 × 10⁻³ |
| Example 2 | ALD | titanium oxide/ | <5 × 10⁻⁴ |
| | | aluminum oxide | |
| Comparative | PECVD | silicon oxide (SiOₓ) | 0.5 |
| Example 6 | | | |
| Comparative | Evaporation | Aluminum | 0.31-1.55 |
| Example 7 | | | |
| Comparative | sputtering | aluminum | 4.3 |
| Example 8 | | oxynitride (AlOₓN_{y}) | |

This Test Example demonstrates that in the preparation method provided by the present invention, when the atomic layer deposition was used, a passivation layer with a low moisture penetration can be obtained. On the other hand, in Comparative Examples 6 to 8, the passivation layers prepared by the plasma-assisted chemical vapor deposition, the evaporation, or the sputtering had greater moisture penetrations. Thus, the method for preparing a titanium oxide film and the method for preparing a composite film comprising a titanium oxide film of the present invention can provide a passivation layer having excellent gas barrier effect to efficiently protect the oxide semiconductor layer from the influence of the ambient air, whereby preventing the deterioration.

Although the present invention has been explained in relation to its preferred embodiment, it is to be understood that many other possible modifications and variations can be made without departing from the spirit and scope of the invention as hereinafter claimed.

What is claimed is:

1. A method for preparing a titanium oxide film, comprising:
(A) providing a metal alkoxide compound and water in contact with a semiconductor substrate: and
(B) using the metal alkoxide compound as a precursor to form a titanium oxide film on a surface of the semiconductor substrate by an atomic layer deposition.

2. The method of claim 1, wherein in the step (A), the metal alkoxide compound is at least one compound represented by Formula (I): 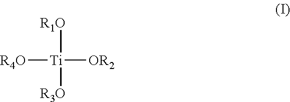
wherein, each R₁, R₂, R₃, and R₄ are independently selected from a branched or linear C₁₋₁₀ alkyl group.

3. The method of claim 2, wherein the metal alkoxide compound is at least one selected from the group consisting of: Ti(OCH₃)₄, Ti(OC₂H₅)₄, Ti[OCH(CH₃)₂]₄, Ti(OC₄H₉)₄, and Ti[OCH₂CH(C₂H₅)(CH₂)₃CH₃]₄.

4. The method of claim 1, wherein in the step (A), the semiconductor substrate is an oxide semiconductor substrate.

5. The method of claim 4, wherein the oxide semiconductor substrate is made of at least one selected from the group consisting of: zinc oxide, tin oxide, iron oxide, chromium oxide, indium oxide, copper oxide, nickel oxide, and cadmium oxide.

6. The method of claim 1, wherein in the step (A), the metal alkoxide compound is heated to 60-150° C.

7. The method of claim 1, wherein in the step (B), the atomic layer deposition is a thermally activated atomic deposition.

8. The method of claim 1, wherein the titanium oxide film has a gas penetration of 0.1 g/m²-day or less.

9. A method for preparing a composite film comprising a titanium oxide film, comprising:
(A) providing a metal alkoxide compound and water in contact with a semiconductor substrate: and
(B) using the metal alkoxide compound as a precursor to form a titanium oxide film on a surface of the semiconductor substrate by an atomic layer deposition; and
(C) depositing at least one metal oxide film on the titanium oxide film to form a composite film.

10. The method of claim 9, wherein in the step (A), the metal alkoxide compound as the precursor is at least one compound represented by Formula (I): 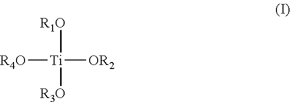
wherein, each R₁, R₂, R₃, and R₄ are independently selected from a branched or linear C₁₋₁₀ alkyl group.

11. The method of claim 10, wherein the metal alkoxide compound is at least one selected from the group consisting of: Ti(OCH₃)₄, Ti(OC₂H₅)₄, Ti[OCH(CH₃)₂]₄, Ti(OC₄H₉)₄, and Ti[OCH₂CH(C₂H₅)(CH₂)₃CH₃]₄.

12. The method of claim 9, wherein in the step (A), the semiconductor substrate is an oxide semiconductor substrate.

13. The method of claim 12, wherein the oxide semiconductor substrate is made of at least one selected from the group consisting of: zinc oxide, tin oxide, iron oxide, chromium oxide, indium oxide, copper oxide, nickel oxide, and cadmium oxide.

14. The method of claim 9, wherein in the step (A), the metal alkoxide compound is heated to 60-150° C.

15. The method of claim 9, wherein in the step (B), the atomic layer deposition is a thermally activated atomic deposition.

16. The method of claim 9, wherein in the step (C), the metal oxide film is made of at least one selected from the group consisting of: titanium oxide, aluminum oxide, hafnium oxide, and zirconium oxide.

17. The method of claim 9, wherein in the step (C), the metal oxide film is deposited by an atomic layer deposition, a chemical vapor deposition, or a physical vapor deposition.

18. The method of claim 9, wherein the titanium oxide film has a gas penetration of 0.1 g/m²-day or less.
